(19) United States
(12) Patent Application Publication
(10) Pub. No.: US 2013/0048353 A1
(43) Pub. Date: Feb. 28, 2013

(54) TRANSPARENT CONDUCTIVE FILM AND TOUCH PANEL USING THE SAME

(71) Applicants: MING-TIEN LIN, Tu-Cheng (TW); PO-SHENG SHIH, Tu-Cheng (TW)

(72) Inventors: MING-TIEN LIN, Tu-Cheng (TW); PO-SHENG SHIH, Tu-Cheng (TW)

(73) Assignee: SHIH HUA TECHNOLOGY LTD., Zhunan (TW)

(21) Appl. No.: 13/340,069

(22) Filed: Dec. 29, 2011

(30) Foreign Application Priority Data
Aug. 31, 2011 (TW) 100131251

(51) Int. Cl. H05K 1/09; H05K 1/11

(52) U.S. Cl. 174/257; 174/261

(57) ABSTRACT

A transparent conductive film a number of first transparent conductive stripes and a number of transparent conductive stripes electrically connected with each other. The first conductive stripes are spaced from each other and extend substantially along a first direction, and the second transparent conductive stripes are spaced from each other and extend substantially along a second direction. The plurality of second transparent conductive stripes are disposed between and electrically connected to adjacent first transparent conductive stripes. The first transparent conductive stripes and the second conductive stripes are arranged in patterns such that the transparent conductive film has an anisotropic impedance. One of the first direction and the second direction is a low impedance direction. A resistivity of the transparent conductive film in the low impedance direction is smaller than the resistivity of the transparent conductive film in any other direction.

This application claims all benefits accruing under 35 U.S.C. §119 from Taiwan Patent Application No. 100131251, filed on Aug. 31, 2011, in the Taiwan Intellectual Property Office, the contents of which are hereby incorporated by reference. This application is related to commonly-assigned applications entitled, “TRANSPARENT CONDUCTIVE FILM AND TOUCH PANEL USING THE SAME,” filed ______ (Atty. Docket No. US41147); and “TRANSPARENT CONDUCTIVE FILM AND TOUCH PANEL USING THE SAME,” filed ______ (Atty. Docket No. US41148).

### BACKGROUND

1. Technical Field

The present disclosure relates to a transparent conductive film and a touch panel using the same.

2. Description of Related Art

The main component of touch panels are transparent conductive films as touch sensing mediums. Materials such as indium tin oxide (ITO), stannic oxide (SnO₂), and zinc oxide (ZnO) are commonly used transparent conductive film materials. ITO has been widely used in the touch panels because it has a high light transmittance, good conductivity, and easily etched.

However, the touch panels can only detect a single touch at one time, and a detecting precision is relatively low.

What is needed, therefore, is to provide a transparent conductive film and a touch panel using the transparent conductive film which can realize multi-touch detecting and can improve the detecting precision of touch points operated thereon.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is a top view of a transparent conductive film of Example 1.

FIG. 2 is a top view of an embodiment of the transparent conductive film in which a second direction is a low impedance direction.

FIG. 3 is a top view of an embodiment of the transparent conductive film including a plurality of cambered stripes.

FIG. 4 is a top view of an embodiment of the transparent conductive film including a plurality of first transparent conductive stripes with varied widths.

FIG. 5 is a top view of the transparent conductive film of Example 2.

FIG. 6 is a top view of the transparent conductive film of Example 3.

FIG. 7 is a top view of an embodiment of a touch panel.

FIG. 8 is a side view of the touch panel.

FIG. 9 is a chart showing variation value curves of voltage of touch points acted on the touch panel.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

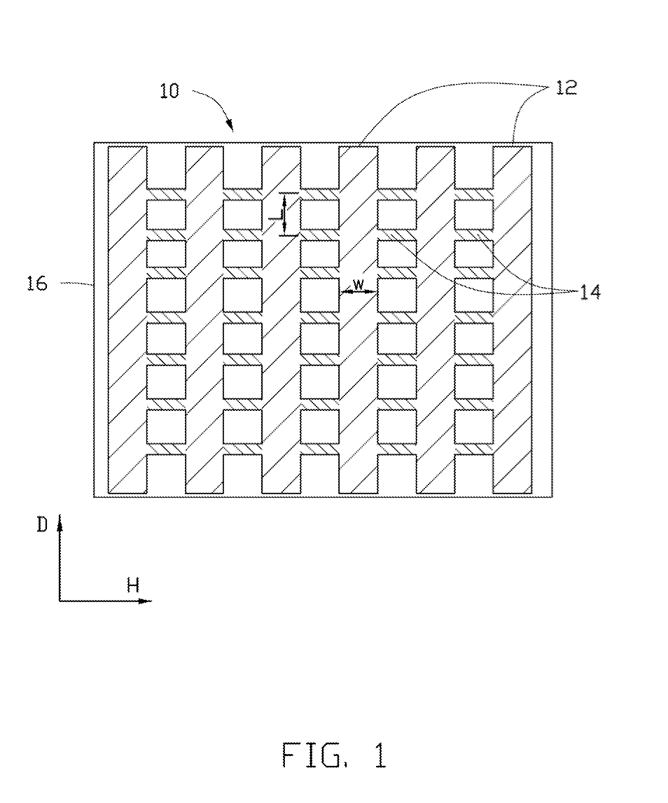

Referring to FIG. 1, one embodiment of a transparent conductive film 10 includes a plurality of transparent conductive stripes connected with each other and extending along different directions. The plurality of transparent conductive stripes are arranged in patterns such that the transparent conductive film 10 can have an anisotropic impedance. Anisotropic impedance means that the transparent conductive film 10 has different impedances along different directions substantially parallel with a surface of the transparent conductive film 10. The extending directions of the plurality of transparent conductive stripes are substantially parallel with a surface of the transparent conductive film 10. The plurality of transparent conductive stripes can include a plurality of first transparent conductive stripes 12 and a plurality of second transparent conductive stripes 14. The plurality of first transparent conductive stripes 12 are spaced from each other and extend substantially along a first direction. The plurality of second transparent conductive stripes 14 are spaced from each other and extend substantially along a second direction. The plurality of second transparent conductive stripes 14 are disposed between and electrically connected to adjacent first transparent conductive stripes 12. One of the first direction and the second direction can be defined as a low impedance direction D. A resistivity of the transparent conductive film 10 in the low impedance direction D is smaller than the resistivity in any other direction. The term “direction” in the present disclosure refers to a direction substantially parallel with the surface of the transparent conductive film 10.

There is no common part between the plurality of first and second transparent conductive stripes 12, 14 extending along the different directions. For example, one first transparent conductive stripe 12 starts from an edge of one second transparent conductive stripe 14 and ends in an edge of another second transparent conductive stripe 14. In one embodiment, there is no common part between each of the plurality of first transparent conductive stripes 12 and each of the plurality of second transparent conductive stripes 14. Each of the plurality of second transparent conductive stripes 14 is disposed between and electrically connected with adjacent first transparent conductive stripes 12.

The transparent conductive film 10 has different resistivities in different directions because the transparent conductive film 10 has different microstructures electrically connected with each other in different directions. These microstructures have different resistances, thus the transparent conductive film 10 has an anisotropic impedance. These microstructures can be the plurality of transparent conductive stripes. The plurality of transparent conductive stripes have different resistances in different directions.

Materials of the plurality of transparent conductive stripes with different resistances in different directions can be the same or different. In one embodiment, the materials are the same, and the transparent conductive film 10 can be formed by the following steps: providing a uniform transparent conductive layer; and patterning the transparent conductive layer to form the plurality of conductive stripes with different lengths and widths to have different impedances along different directions. In one embodiment, the materials have different conductivities to form the plurality of conductive stripes connected and extend along different directions. In addition, the lengths and widths of the plurality of the conductive stripes can be further varied to increase the impedance differences of the transparent conductive film 10 in different directions. In another embodiment, a number of the conductive stripes in one direction can be much greater than the number of the conductive stripes in other directions so that the transparent conductive film 10 has a good anisotropic impedance.

One of the first direction and the second direction is the low impedance direction D, and the other direction can be a high impedance direction H. The resistivity of the transparent conductive film 10 in the high impedance direction H is greater than the resistivity in any other direction. The transparent conductive film 10 is conductive in any direction.

A resistivity ratio of the transparent conductive film 10 in the low impedance direction D and high impedance direction H can be about 1:30 to about 1:1000. In one embodiment, the resistivity ratio is about 1:50 to about 1:200. An intersection angle of the low impedance direction D and the high impedance direction H can be in a range from about 10 degrees to about 90 degrees. In one embodiment, the low impedance direction D is substantially perpendicular to the high impedance direction H.

If the first direction is the low impedance direction D, each of the plurality of first transparent conductive stripes 12 can be a one dimensional conductor extending substantially along the first direction, and one or each of the plurality of second transparent conductive stripes 14 can be a one-dimensional or two-dimensional conductor. The plurality of second transparent conductive stripes 14 between adjacent first transparent conductive stripes 12 can be spaced from or intersect each other. The extending directions of the plurality of second transparent conductive stripes 14 may not be limited as long as the resistivity of the transparent conductive film 10 in the low impedance direction D is much smaller than the resistivity in any other direction.

Referring to FIG. 1, in one embodiment, the first direction is the low impedance direction D, and the second direction is the high impedance direction H. The plurality of first transparent conductive stripes 12 have a high conductivity in the lengthwise direction and substantially extend along the low impedance direction D. The plurality of second transparent conductive stripes 14 have a low conductivity in the lengthwise direction and substantially extend along the high impedance direction H. Impedances of the plurality of first transparent conductive stripes 12 are much smaller than the impedances of the transparent conductive film 10 in any other direction. The impedances of the plurality of second transparent conductive stripes 14 are much greater than the impedances of the transparent conductive film 10 in any other direction. The plurality of second transparent conductive stripes 14 are disposed between and connected to adjacent first transparent conductive stripes 12 to form a network. In one embodiment, the material of the plurality of first transparent conductive stripes 12 and the plurality of second transparent conductive stripes are the same. Each of the plurality of first transparent conductive stripes 12 is long in length or has a great width to have a low impedance, and each of the plurality of second transparent conductive stripes 14 is short in length or has a small width to have a high impedance. A width ratio of each of the first transparent conductive stripes 12 and each of the second transparent conductive stripes 14 can be in a range from about 100:1 to about 500:1. In one embodiment, the material of the plurality of first transparent conductive stripes 12 and the plurality of second transparent conductive stripes 14 are different. A material with a high conductivity can be used to fabricate the plurality of first transparent conductive stripes 12 extending along the low impedance direction D. A material with a low conductivity can be used to fabricate the plurality of second transparent conductive stripes 14 extending substantially along the high impedance direction H. In addition, the length or width of the plurality of first transparent conductive stripes 12 and the plurality of second transparent conductive stripes 14 can vary with the materials thereof to increase the anisotropic impedance of the transparent conductive film 10.

If the second direction is the low impedance direction D, each of the plurality of second transparent conductive stripes 14 can be a one-dimensional conductor extending substantially along the second direction, and one or each of the plurality of first transparent conductive stripes 12 can be a one-dimensional or two-dimensional conductor. Adjacent first transparent conductive stripes 12 can be spaced from or intersect each other. The extending directions of the plurality of first transparent conductive stripes 12 may not be limited as long as the resistivity of the transparent conductive film 10 along the second direction is much smaller than the resistivity in any other direction.

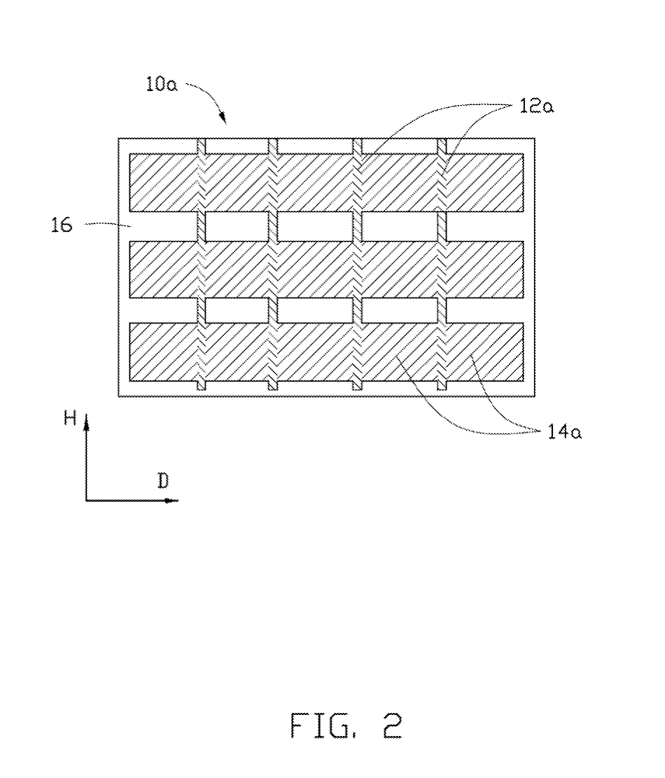

Referring to FIG. 2, in another embodiment, the second direction is the low impedance direction D, and the first direction is the high impedance direction H. The plurality of first transparent conductive stripes 12a have a low conductivity in the lengthwise direction and extend substantially along the high impedance direction H. The plurality of second transparent conductive stripes 14a have a high conductivity in the lengthwise direction and substantially extend along the low impedance direction D. Impedances of the plurality of first transparent conductive stripes 12a are much greater than the impedances of the transparent conductive film 10a in other directions. The impedances of the plurality of second transparent conductive stripes 14a are much smaller than the impedances of the transparent conductive film 10a in other directions.

In one embodiment, the material of the plurality of first transparent conductive stripes 12 and the plurality of second transparent conductive stripes are the same. Each of the plurality of first transparent conductive stripes 12 is long in length or has a great width to have a low impedance in the extending direction, and each of the plurality of second transparent conductive stripes 14 is short in length or has a small width to have a high impedance in the extending direction. A width ratio of each of the first transparent conductive stripes 12 and each of the second transparent conductive stripes 14 can be in a range from about 100:1 to about 500:1. In one embodiment, the material of the plurality of first transparent conductive stripes 12 and the plurality of second transparent conductive stripes 14 are different. A material with a high conductivity can be used to fabricate the plurality of first transparent conductive stripes 12 extending substantially along the low impedance direction D. A material with a low conductivity can be used to fabricate the plurality of second transparent conductive stripes 14 substantially extending along the high impedance direction H. In addition, the length or width of the plurality of first transparent conductive stripes 12 and the plurality of second transparent conductive stripes 14 can vary with the materials thereof at the same time.

The material of the plurality of first transparent conductive stripes 12 and the plurality of second transparent conductive stripes 14 can be a transparent conductive material. The transparent conductive material can be a metal oxide, a metal nitride, a metal fluoride, a conductive polymer, a carbon containing material, or combinations thereof. The metal oxide can include a single metal element such as stannic oxide (SnO₂), zinc oxide, cadmium oxide (CdO), or indium oxide (In₂O₃). The metal oxide also can include two or more metal elements such as indium tin oxide (ITO), indium zinc oxide (IZO), gallium zinc oxide (GZO), aluminum zinc oxide (AZO). The metal oxide can be a mixture of at least two metal oxides such as In₂O₃—ZnO, CdIn₂O₄, Zn₂SnO₄, or combinations thereof. The metal nitride can be titanium nitride (TiN). The metal fluoride can be fluoride mixed stannic oxide. The conductive polymer can be poly(3,4-ethylenedioxythiophen) (PEDOT) or a composition of PEDOT and polystyrene sulfonate (PEDOT-PSS). The carbon containing material can be graphene or a carbon nanotube transparent conductive film. The carbon nanotube transparent conductive film can be a transparent conductive film consisting primarily of carbon nanotubes or a composite film including the carbon nanotubes and other transparent conductive materials. In one embodiment, the material of the transparent conductive film 10 is ITO.

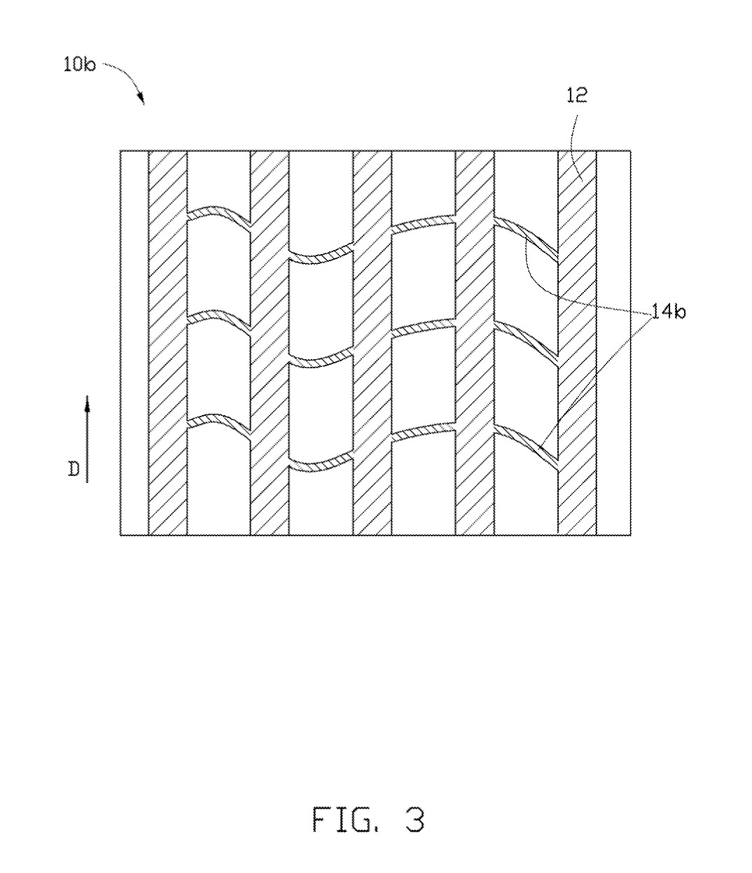

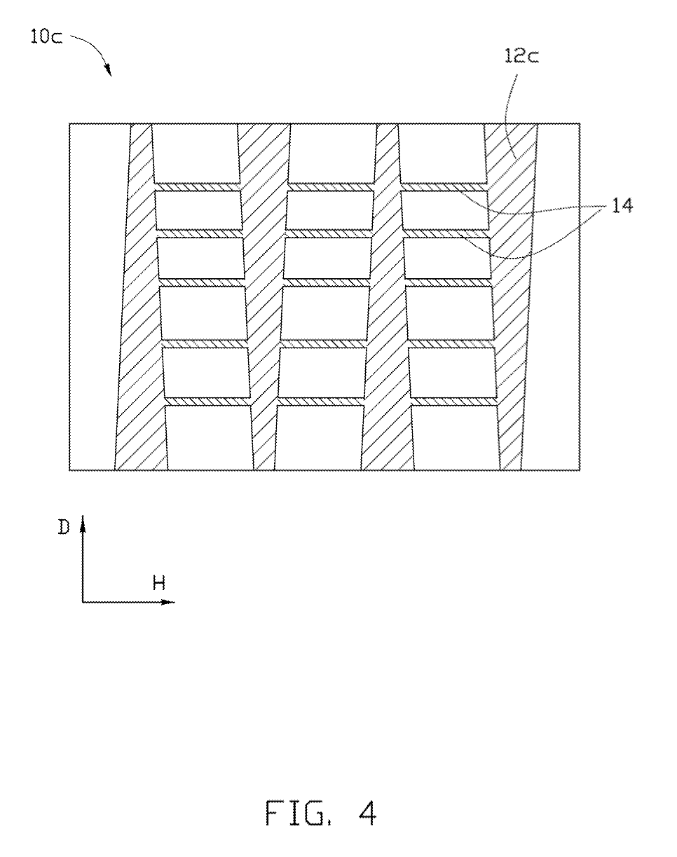

The plurality of first transparent conductive stripes 12 and the plurality of second transparent conductive stripes 14 can have various shapes as long as the resistivity of the transparent conductive film 10 along the low impedance direction D is much smaller the resistivity in other directions. At least one of the plurality of first transparent conductive stripes 12 and the plurality of second transparent conductive stripes 14 can be a straight stripe, a square wave stripe, a curve wave stripe, a zigzag stripe, a stepped shaped stripe, or a cambered stripe. Referring to FIG. 1, in one embodiment, each of the plurality of first transparent conductive stripes 12 and the plurality of second transparent conductive stripes 12 is the straight stripe. Referring to FIG. 3 of the transparent conductive film 10b, in one embodiment, each of the plurality of first transparent conductive stripes 12 is the straight stripe, and each of the plurality of second transparent stripes 14b is the cambered stripe. Each of the plurality of first transparent conductive stripes 12 and each of the plurality of second transparent conductive stripes 14 can have a substantially equal width or a varied width. Referring to FIG. 4 of the transparent conductive film 10c, in one embodiment, each of the plurality of first transparent conductive stripes 12c has the varied width. Shapes of the plurality of first transparent conductive stripes 12 and the plurality of second transparent conductive stripes 14 can be the same or different. A conductive or impedance diversity of the transparent conductive film 10 in the different directions can be increased by varying the shapes of the first transparent conductive stripes 12 and the second transparent conductive stripes 14.

A distance between adjacent second transparent conductive stripes 14 disposed between adjacent first transparent conductive stripes 12 can be substantially the same or varied. The distance between adjacent first transparent conductive stripes 12 and adjacent second transparent conductive stripes 14 may be set so as not to be visually sensed. As shown in FIG. 1, the distance between two adjacent first transparent conductive stripes 12 is labeled with W, and the distance between two adjacent second transparent conductive stripes 14 is labeled with L. In one embodiment, adjacent first transparent conductive stripes 12 and adjacent second transparent conductive stripes 14 are disposed with substantially equal distances. W can be less than or equal to about 50 micrometers. In one embodiment, W is about 30 micrometers. L can be less than or equal to about 10 micrometers. In one embodiment, L is about 5 micrometers.

The distances W, L, and the width ratio of the first transparent conductive stripe 12 and the second transparent conductive stripe 14 can be varied according to different applications or properties of the transparent conductive film 10, such as the size of the touch panel.

A number of the second transparent conductive stripes 14 between the adjacent first transparent conductive stripes 12 can be the same or different. Adjacent second transparent conductive stripes 14 can extend substantially along a straight line or stagger.

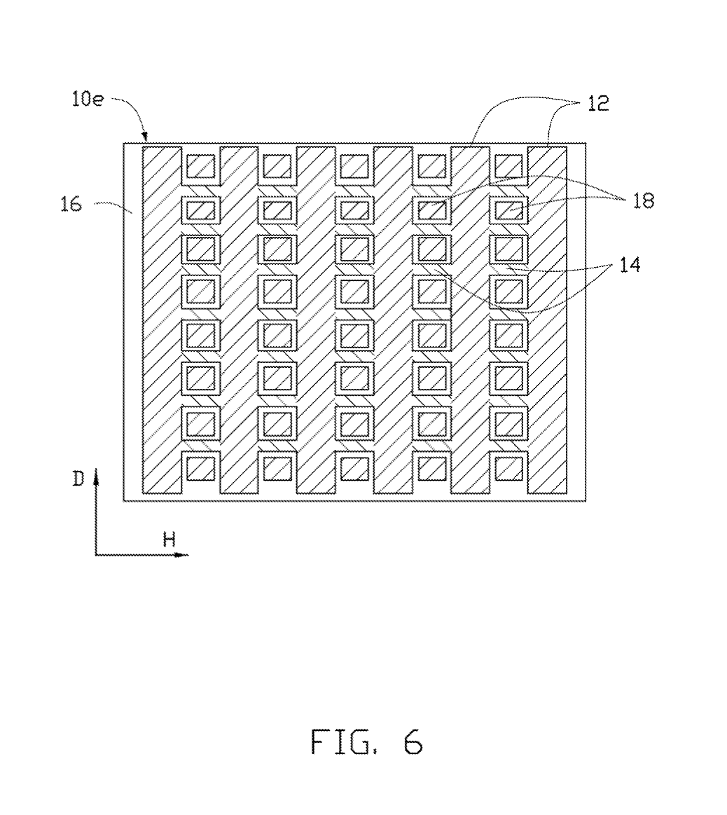

Referring to FIG. 6, the transparent conductive film 10e can include a plurality of optical compensation films 18 disposed between the adjacent first transparent conductive stripes 12 or the adjacent second transparent conductive stripes 14. Each optical compensation film 18 is spaced from each first transparent conductive stripe 12 and each second transparent conductive stripe 14. Each optical compensation film 18 can be a continuous film or a plurality of continuous sub-films spaced from each other. The plurality of first transparent conductive stripes 12 and the plurality of second transparent conductive stripes 14 cannot be visually sensed easily by disposing the plurality of optical compensation films 18. The plurality of optical compensation films 18 can have a similar transmittance and use the same material with the plurality of first transparent conductive stripes 12 and the plurality of second transparent conductive stripes 14. The shapes of the plurality of optical compensation films 18 is not limited as long as the optical compensation films 18 are insulated with the plurality of first transparent conductive stripes 12 and the plurality of second transparent conductive stripes 14. In one embodiment, the shape of each optical compensation film 18 is a rectangle. The plurality of optical compensation films 18 can be formed by patterning with the plurality of first transparent conductive stripes 12 and the plurality of second transparent conductive stripes 14 at the same time or disposed separately.

The plurality of transparent conductive stripes connected with each other along the different directions can be formed at the same time or separately by various patterning methods. The patterning methods can be screen printing or etching a whole transparent conductive layer according to the patterns. In one embodiment, the transparent conductive film 10 is formed by the method of patterning the whole transparent conductive layer, and the transparent conductive layer is made of only one material. In this condition, the plurality of transparent conductive stripes can be seamlessly connected with each other along the different directions. The method can include the following steps:

S1, providing a substrate 16;

S2, disposing the transparent conductive material on a surface of the substrate 16 to form the transparent conductive layer; and

S3, patterning the transparent conductive layer to form the plurality of first transparent conductive stripes 12 and the plurality of second transparent conductive stripes 14.

In step S1, the substrate 16 is a supporting component and can be a transparent substrate. A material of the transparent substrate can be a glass or transparent polymer. The transparent polymer can be polymethylmethacrylate (PMMA), polyethylene terephthalate (PET), polycarbonate (PC), or combinations thereof.

In step S2, the transparent conductive layer can be formed by a method such as vacuum evaporation, sputtering, ion plating, vacuum plasma CVD, spray pyrolysis, thermal CVD, or sol-gel. In one embodiment, ITO is sputtered on the surface of the substrate 16 to form the transparent conductive layer.

In step S3, the patterning process is conducted based on a desired structure of the transparent conductive film 10 and the low impedance direction D. The plurality of optical compensation films 18 can be patterned at the same time with the plurality of first transparent conductive stripes 12 and the plurality of second transparent conductive stripes 14. The patterning method can include bump transfer printing, wet etching, dry etching, laser etching, shave removing, or tape peeling.

The shave removing method is conducted by shaving unwanted parts in the transparent conductive layer using a tool such as a blade or file. The tape peeling method is conducted by adhering the tape on the unwanted parts of the transparent conductive layer, and peeling the tape. The unwanted parts of the transparent conductive layer will adhere on the peeled tape and the layer can be patterned into the desired transparent conductive film 10. The laser etching method is conducted by ablating the unwanted parts of the transparent conductive layer using a laser. The wet etching and dry etching methods can be conducted by putting desired pattern-photoresist on the surface of the transparent conductive layer by photolithography, and ion bombarding or liquid etching the unwanted parts of the layer to form the patterned transparent conductive film 10. The method of bump transfer printing can be conducted by designing a mold having the shape of the unwanted parts of the layer, adhering the mold on the surface of the transparent conductive layer, and peeling the mold to leave the desired pattern on the substrate 16. In one embodiment, the plurality of first transparent conductive stripes 12, the plurality of second transparent conductive stripes 14, and the plurality of optical compensation films 18 are patterned by laser etching.

The following examples further illustrate transparent conductive film 10 and the method for making thereof, wherein the first direction is the low impedance direction D, and the second direction is the high impedance direction H.

### EXAMPLE 1

The transparent conductive materials of ITO are sputtered on the surface of the substrate of PET to form the transparent conductive layer. The transparent conductive layer is laser etched to form the plurality of first transparent conductive stripes 12 substantially along the low impedance direction D and the plurality of second transparent conductive stripes 14 substantially along the high impedance direction H. Each of the plurality of first transparent conductive stripes 12 is the straight stripe and has a substantially same width. Referring to FIG. 1, the plurality of first transparent conductive stripes 12 is substantially perpendicular to the plurality of second transparent conductive stripes 14. The distance W is about 30 micrometers, and the distance L is about 5 millimeters.

### EXAMPLE 2

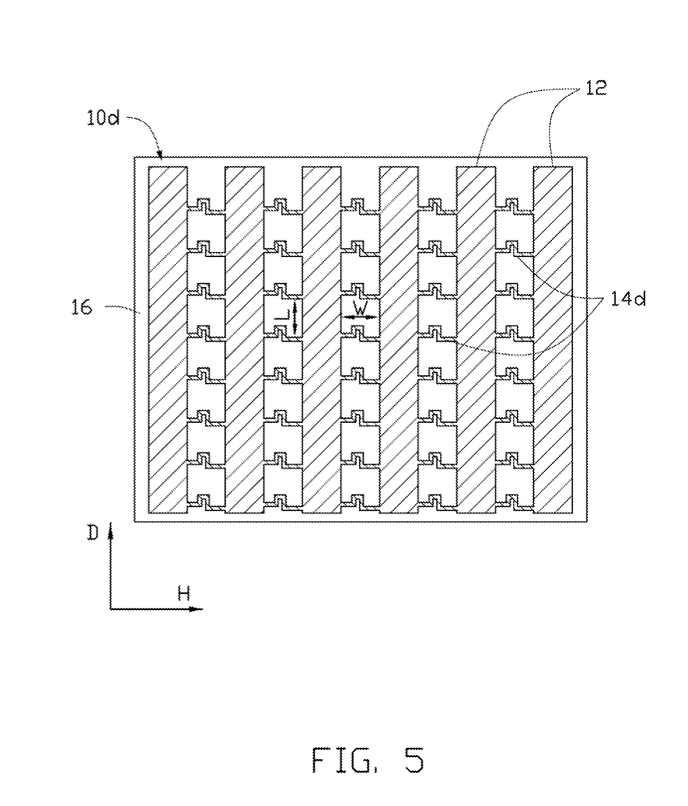

Referring to FIG. 5, the transparent conductive film 10d is fabricated by the same method as in Example 1, except that each of the second transparent conductive stripes 14d is the square wave stripe to increase the resistivity thereof.

### EXAMPLE 3

Referring to FIG. 6, the transparent conductive film 10e is fabricated by the same method as in Example 1, except that the plurality of optical compensation films 18 are laser etched at the same time with the plurality of first transparent conductive stripes 12 and the plurality of second transparent conductive stripes 14.

One embodiment of a touch panel includes at least one transparent conductive film 10, a substrate, and a plurality of electrodes. The at least one transparent conductive film 10 is disposed on a surface of the substrate and on a range capable of sensing the touch points on the touch panel. The plurality of electrodes are spaced from each other and electrically connected with the at least one transparent conductive film 10. In one embodiment, the plurality of electrodes is disposed on one side or two opposite sides of the touch panel. The one or two opposite sides are substantially perpendicular to the low impedance direction D.

The touch panel can be a resistive touch panel or a capacitive touch panel. The touch panel can realize multi-touch detecting by using the transparent conductive film 10. In addition, signals detected from the plurality of electrodes before and after touching on the touch panel vary significantly because of the electric or anisotropic impedance of the transparent conductive film 10. Therefore, position coordinates of the touch points can be easily detected, and a precision of the detection is improved.

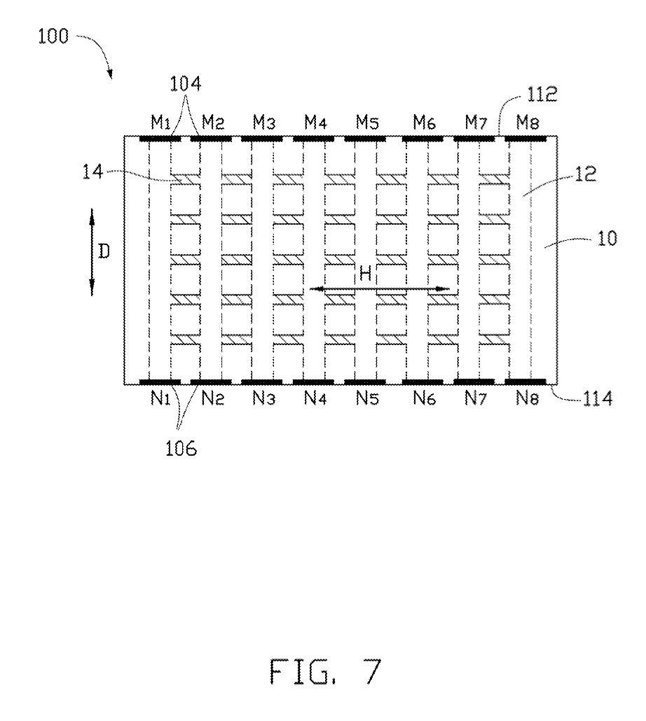

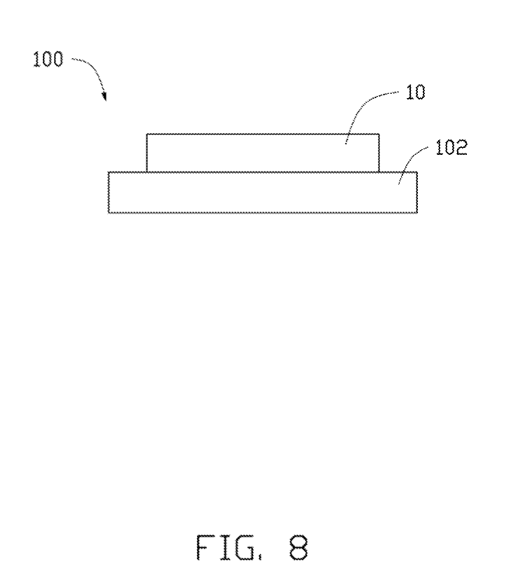

Referring to FIG. 7 and FIG. 8, one embodiment of a surface capacitive touch panel 100 using a single transparent conductive film 10 is provided. The touch panel 100 includes a substrate 102, the single transparent conductive film 10, and a plurality of first electrodes 104 and a plurality of second electrodes 106. The transparent conductive film 10 is disposed on a surface of the substrate 102. The plurality of first electrodes 104 and the plurality of second electrodes 106 are disposed on two opposite sides of the transparent conductive film 10. Both of the two opposite sides are substantially perpendicular to the low impedance direction D of the transparent conductive film 10. The side of the transparent conductive film 10 with the plurality of first electrodes disposed thereon is defined as a first side 112, and the side of the transparent conductive film 10 with the plurality of second electrodes disposed thereon is defined as a second side 114. Each of the plurality of first electrodes 102 corresponds to each of the plurality of second electrodes 104 substantially along the low impedance direction D.

In one embodiment, the transparent conductive film 10 of FIG. 1 is used in the touch panel 100. A number of the plurality of first transparent conductive stripes 12 can be greater than or equal to the number of the plurality of first electrodes 104 or the plurality of second electrodes 106. In one embodiment, the number of the plurality of first transparent conductive stripes 12 is equal to the number of the plurality of first electrodes 104 and the number of the plurality of second electrodes 106. One end of the first transparent conductive stripe 12 along the extending direction is electrically connected with one first electrode 104, and the other end along the extending direction is electrically connected with one second electrode 106. The plurality of first electrodes 104 and second electrodes 106 can be driving electrodes used for inputting driving signals to drive the touch panel 100 and can be sensing electrodes used for detecting sensed signals. A driving and sensing process can be realized by a control circuit in the touch panel 100.

When a conductor, such as fingers or other conductors, touches the touch panel 100, a coupling capacitance can be generated between the conductor and the transparent conductive film 10. The coupling capacitance will cause a signal variation detected from the first electrodes 104 and second electrodes 106 before and after touching. The touch points can be detected according to the signal variation. The touch points can be detected according to the following steps:

B1, providing a driving signal to each of the plurality of first electrodes 104 and each of the plurality of second electrodes 106;

B2, touching the touch panel 100 by using the conductor to generate the coupling capacitance;

B3, detecting sensed signals from the plurality of first electrodes 104 and the plurality of second electrodes 106; and

B4, calculating the position coordinates of the touch points by analyzing the sensed signals.

In step B1, the driving signal can be voltage or current. In one embodiment, the driving signal is voltage.

In step B3, the sensed signals can be voltage, current, electric quantity, capacity, or a variation value thereof before and after touching. In one embodiment, the sensed signals are represented by a variation value curve of the voltage. The variation value curve consists of a plurality of voltage variation value before and after touching the touch panel 100. The variation value curve of the voltage detected from the plurality of first electrodes 104 is defined as a first curve, and the variation value curve of the voltage detected from the plurality of second electrodes 106 is defined as a second curve.

In step B4, the position coordinates of the touch points can be calculated according to the sensed signals obtained before and after touching the touch panel 100. In one embodiment, a method for calculating the position coordinates of the touch points acted on the touch panel 100 includes the following steps:

B41, calculating the position coordinates of the touch points in the high impedance direction H according to the first curve or the second curve; and

B42, calculating the position coordinates of the touch points in the low impedance direction D according to the first curve and the second curve.

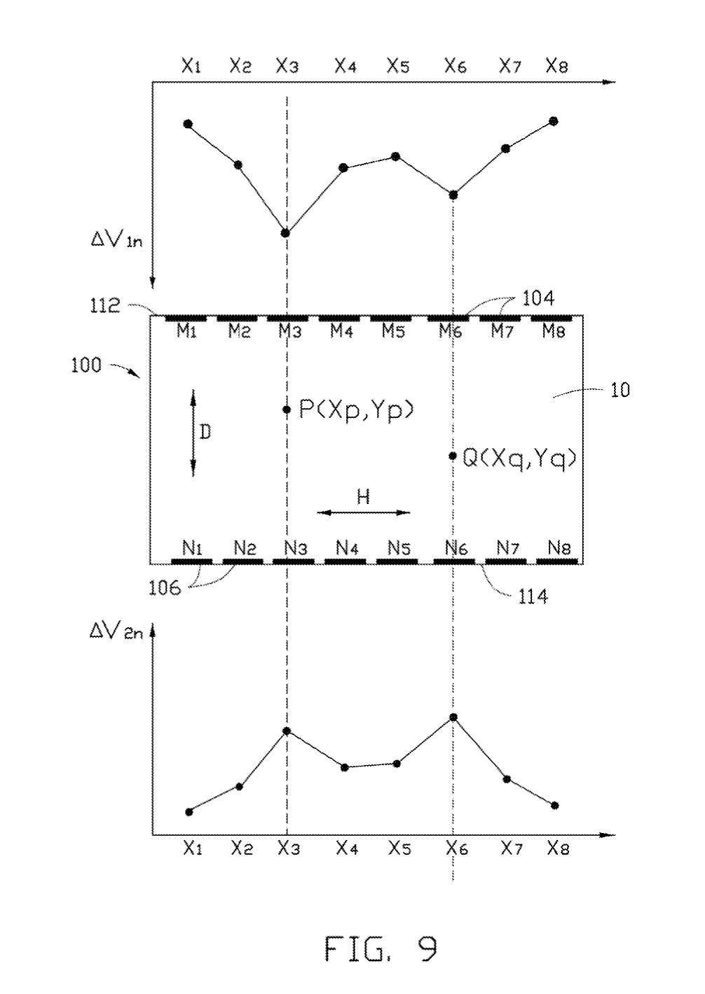

Referring to FIG. 9, a schematic figure about the first curve and the second curve is provided. Parameters and labels are clarified first. P and Q represent two touch points acted on the touch panel 100 at the same time. The position coordinates of touch point P is represented by (xₚ, yₚ), and the position coordinates of the touch point Q is represented by (x_{q}, y_{q}). yₚ represents a distance perpendicular from the touch point P to the first side 112, and y_{q} represents a distance perpendicular from the touch point Q to the first side 112. The plurality of first electrodes 104 are labeled as M₁, M₂, M₃, M₄, M₅, M₆, M₇, and M₈. The plurality of second electrodes 106 are labeled as N₁, N₂, N₃, N₄, N₅, N₆, N₇, and N₈. The position coordinates of the plurality of first electrodes 104 and the plurality of second electrodes 106 in the high impedance direction H are orderly labeled as X₁, X₂, X₃, X₄, X₅, X₆, X₇, and X₈. ΔV₁ᵢ represents the variation value of the voltage detected from the first electrode Mᵢ before and after touching the touch panel 100. ΔV₂ᵢ represents the variation value of the voltage detected from the second electrode Nᵢ before and after touching the touch panel 100, wherein i represents a number order of the first or second electrode, and i=1, 2, . . . 8.

(1) Confirming the Position Coordinates of the Touch Points P and Q in the High Impedance Direction H

The position coordinates of the touch points P and Q in the high impedance direction H can be obtained from one of the first curve and second curve. In one embodiment, one or more peak values in the first curve are found to calculate the position coordinates of the touch points P and Q in the high impedance direction H. Referring to FIG. 9, the variation value ΔV₁₃ detected from the M₃ and the variation value ΔV₁₆ detected from the M₆ are two peak values in the first curve. M₃ corresponds to the coordinate X₃ and M₅ corresponds to the coordinate X₅. Therefore, the position coordinates xₚ and x_{q} of the touch points P and Q can be directly judged from the first curve: xₚ=X₃, and x_{q}=X₅. In addition, the variation values detected from the electrodes adjacent to the electrodes in which the peak values are detected can be used to calculate the position coordinates of the touch points for a better precision. For example, M₂ and M₄ are adjacent to M₃, the position coordinate xₚ of the touch point P can be calculated by a formula:

$${x}_{p} = \frac{{X}_{2} Δ {V}_{12} + {X}_{4} Δ {V}_{14}}{Δ {V}_{12} + Δ {V}_{14}} .$$

Correspondingly, the position coordinate x_{q} can be calculated by a formula:

$${x}_{q} = \frac{{X}_{5} Δ {V}_{15} + {X}_{7} Δ {V}_{17}}{Δ {V}_{15} + Δ {V}_{17}} .$$

(2) Confirming the Position Coordinates of the Touch Points P and Q in the Low Impedance Direction D

The one or more peak values in the first curve and in the second curve are found to calculate the position coordinates of the touch points P and Q in the low impedance direction D. The transparent conductive film 10 has an anisotropic impedance property. The closer the touch points to the first electrodes 104 or the second electrodes 106 in the low impedance direction D, the greater the variation values detected from the corresponding first electrodes 104 or the corresponding second electrodes 106. Referring to FIG. 9, taking touch point P for example, a distance from the touch point P to the first electrode M₃ is smaller than the distance to the second electrode N₃, so the peak variation value ΔV₁₃ is greater than the peak variation value ΔV₂₃. The variation value is inversely proportional to the distance from the touch point to the corresponding first electrode 104 or second electrode 106. The position coordinate yₚ can be calculated by a formula:

$${y}_{p} = \frac{Δ {V}_{23}}{Δ {V}_{13} + Δ {V}_{23}} \times K ,$$

wherein K represents a distance perpendicular from the first side 112 to the second side 114. In addition, the variation values detected from the electrodes adjacent to the electrodes from which the peak values were detected can be used to calculate the position coordinates of the touch points in the low impedance direction D for a better precision. For example, the position coordinate yₚ can be represented by:

$${y}_{p} = \frac{Δ {V}_{22} + Δ {V}_{23} + Δ {V}_{24}}{Δ {V}_{13} + Δ {V}_{23} + Δ {V}_{12} + Δ {V}_{22} + Δ {V}_{14} + Δ {V}_{24}} \times K .$$

Other formulas can also be used to calculate the position coordinates of the touch points P and Q. The above method can also detect two more touch points.

The transparent conductive film 10 has a good anisotropy impedance property. Therefore, a resistance diversity of the transparent conductive film 10 from one touch point to the different electrodes varies significantly. Consequently, a diversity of the signal variation values are detected from the different electrodes varies significantly. Therefore, one or more touch points can be detected according to a size or sizes of the variation values detected from the electrodes of the touch panel. In addition, a detecting precision of the touch points can be improved by the variation values which varied significantly.

Depending on the embodiment, certain steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A transparent conductive film comprising a plurality of first transparent conductive stripes and a plurality of transparent conductive stripes electrically connected with each other, wherein the plurality of first conductive stripes are spaced from each other and extend substantially along a first direction, and the plurality of second transparent conductive stripes are spaced from each other and extend substantially along a second direction, and the plurality of second transparent conductive stripes are disposed between and electrically connected to adjacent first transparent conductive stripes, the plurality of first transparent conductive stripes and the plurality of second conductive stripes are arranged in patterns such that the transparent conductive film has an anisotropic impedance, one of the first direction and the second direction is a low impedance direction, and a resistivity of the transparent conductive film in the low impedance direction is smaller than the resistivity of the transparent conductive film in any other direction.

2. The transparent conductive film of claim 1, wherein the first direction is the low impedance direction, and the second direction is a high impedance direction, the resistivity of the transparent conductive film along the high impedance direction is greater than the resistivity along any other direction, and a resistivity ratio of the transparent conductive film along the low impedance direction and the high impedance direction is in a range from about 1:30 to about 1:1000.

3. The transparent conductive film of claim 2, wherein a material of the plurality of first transparent conductive stripes is the same as a material of the plurality of second transparent conductive stripes, and a width ratio of one first transparent conductive stripe and one second transparent conductive stripe is in an range from about 100:1 to about 500:1.

4. The transparent conductive film of claim 2, wherein a material of the plurality of first transparent conductive stripes is different from a material of the plurality of second transparent conductive stripes.

5. The transparent conductive film of claim 4, wherein the material of the plurality of first transparent conductive stripes is a transparent and conductive material selected from the group consisting of metal oxide, metal nitride, and metal fluoride, the material of the plurality of second transparent conductive stripes is a transparent and conductive material selected from the group consisting of conductive polymer, carbon nanotubes, and graphene.

6. The transparent conductive film of claim 2, wherein an angle between the low impedance direction and the high impedance direction is in a range from about 10 degrees to about 90 degrees.

7. The transparent conductive film of claim 1, wherein a material of the plurality of first transparent conductive stripes and the plurality of second transparent is a transparent and conductive material selected from the group consisting of metal oxide, metal nitride, metal fluoride, conductive polymer, graphene, and carbon nanotube film comprising a plurality of carbon nanotubes.

8. The transparent conductive film of claim 7, wherein the metal oxide comprises at least one of stannic oxide, zinc oxide, cadmium oxide, indium oxide, indium tin oxide, indium zinc oxide, gallium zinc oxide, and aluminum zinc oxide, the metal nitride comprises titanium nitride; the conductive polymer comprises at least one of poly(3,4-ethylenedioxythiophen) and a composition of PEDOT and polystyrene sulfonate.

9. The transparent conductive film of claim 1, wherein at least one of the plurality of first transparent conductive stripes and the plurality of second transparent conductive stripes is a straight stripe, a square wave stripe, a curve wave stripe, a zigzag stripe, a stepped shaped stripe, a cambered stripe, or combinations thereof.

10. The transparent conductive film of claim 9, wherein a width of one of the plurality of first transparent conductive stripes or the plurality of second transparent conductive stripes is varied along a length thereof.

11. The transparent conductive film of claim 1, wherein a plurality of optical compensation films are disposed between adjacent first transparent conductive stripes of the plurality of first transparent conductive stripes or adjacent second transparent conductive stripes of the plurality of second transparent conductive stripes, and the plurality of optical compensation films are spaced from each of the plurality of first transparent conductive stripe and each of the plurality of second transparent conductive stripe.

12. The transparent conductive film of claim 11, wherein each optical compensation film comprises a plurality of sub-optical-films spaced from each other.

13. A transparent conductive film comprising a plurality of one-dimensional transparent conductive conductors spaced from each other and extending along a first direction, and a plurality of transparent conductors disposed between and electrically connected to adjacent one-dimensional transparent conductive conductors, wherein a resistivity of the transparent conductive film along the first direction is smaller than the resistivity along any other direction.

14. A touch panel comprising a substrate, at least one transparent conductive film disposed on a surface of the substrate, and a plurality of electrodes spaced from each other and electrically connected with the at least one transparent conductive film, wherein the at least one transparent conductive film comprises a plurality of first transparent conductive stripes and a plurality of transparent conductive stripes electrically connected with each other, the plurality of first conductive stripes are spaced from each other and extend substantially along a first direction, and the plurality of second transparent conductive stripes are spaced from each other and extend substantially along a second direction, the plurality of first transparent conductive stripes and the plurality of second conductive stripes are arranged in patterns such that the transparent conductive film has an anisotropic impedance, one of the first direction and the second direction is a low impedance direction, and a resistivity of the transparent conductive film in the low impedance direction is smaller than the resistivity of the transparent conductive film in any other direction.

15. The touch panel of claim 14, wherein a distance between adjacent first transparent conductive stripes is less than or equal to 50 micrometers.

16. The touch panel of claim 14, wherein a distance between adjacent second transparent conductive stripes is less than or equal to 10 millimeters.
